(19) United States
(12) Patent Application Publication
(10) Pub. No.: US 2008/0261399 A1
(43) Pub. Date: Oct. 23, 2008

(54) METHOD FOR CHEMICAL MECHANICAL POLISHING IN A SCAN MANNER OF A SEMICONDUCTOR DEVICE

(76) Inventors: Yong Soo Choi, Seongnam-si (KR); Gyu Hyun Kim, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 11/946,110

(22) Filed: Nov. 28, 2007

(30) Foreign Application Priority Data
Apr. 20, 2007 (KR) 10-2007-0039018

(51) Int. Cl. H01L 21/302

(52) U.S. Cl. 438/692; 257/E21.214

(57) ABSTRACT

The chemical mechanical polishing of a semiconductor device includes polishing a target layer to be polished through a chemical reaction by slurry and a mechanical process by a polishing pad. Then performing a post cleaning composed of cleaning, rinsing and drying of the surface of the polished target layer. The parts for cleaning, rinsing and drying procedures are arranged in a row and the post cleaning is performed in a scan manner using a bar type module. Provided at the cleaning and rinsing parts, a solution supplying nozzle and a retrieving nozzle disposed at both sides of the solution supplying nozzle. Finally, removing the solution supplied to the target layer to be polished immediately after the solution comes in contact with the target layer.

### CROSS-REFERENCE TO RELATED APPLICATIONS

The present application claims priority to Korean patent application number 10-2007-0039018 filed on Apr. 20, 2007, which is incorporated herein by reference in its entirety.

### BACKGROUND OF THE INVENTION

The present invention relates to a method for chemical mechanical polishing (CMP) of a semiconductor device, and more particularly, to a method for chemical mechanical polishing of a semiconductor device to enhance reliability and device properties of a semiconductor device through improving process details.

As high integration of a semiconductor devices progresses, research is currently being made for a method to realize a semiconductor device having various types of recess channels that can ensure an effective channel length.

A method for forming a recess gate of a semiconductor device in accordance with the prior art is as follows.

An isolation layer defining an active region is formed in a semiconductor substrate. Etching the active region in the substrate that is defined by the isolation layer forms a gate recess. A gate insulation layer is subsequently formed over the semiconductor substrate formed with the gate recess. Then, a polysilicon layer is formed over the gate insulation layer to fill the gate recess.

The surface of the polysilicon layer formed on the upper part of the gate recess is uneven. Accordingly, when a tungsten silicide layer is formed over the uneven polysilicon layer, cracking of the tungsten silicide layer occurs on an upper part of the uneven surface. As a result, abnormal oxidation of the tungsten silicide layer occurs in the follow up process that causes a shortage of a gate electrode and a self aligned contact (SAC) failure. Therefore, chemical mechanical polishing is implemented for removing the unevenness of the polysilicon layer surface after the polysilicon layer is formed.

The tungsten silicide layer and a hard mask layer are sequentially formed over the chemical mechanical polished polysilicon layer. The hard mask layer, the tungsten silicide layer, the polysilicon layer, and the gate insulation layer are then sequentially etched to form a recess gate over the gate recess.

However, in the aforementioned prior art, a radial watermark defect results after the CMP of the polysilicon layer. Because of this, poor gate patterning results where the polysilicon layer is not etched in the succeeding etching process for forming a gate. Thus, device properties and reliability of the device are diminished.

Specifically, the CMP includes a post cleaning process that is performed in a brush manner or a wet bath manner to remove slurry residue and polishing the by-product generated in the polishing process. The radial watermark defect that is generated on the surface of the hydrophobic polysilicon layer is caused by a diluted HF solution used in the post cleaning process. Since the watermark includes minute amounts of an oxide layer, the etching is prevented in the succeeding gate etching process thereby resulting in poor gate patterning.

FIG. 1A is a photograph showing that the radial watermark is generated on a resultant substrate after the CMP and FIG. 1B is a photograph showing the poor gate patterning caused by the watermark defect.

Meanwhile, as is well known, a flash memory device is formed using metal wiring for electrically connecting devices together and for connecting wirings together. A method of forming the metal wiring with an aluminum layer using a damascene process has been suggested.

A method for forming a metal wiring of a semiconductor device in accordance with the prior art is as follows.

An etching stop layer and an insulation layer are sequentially deposited over a semiconductor substrate. The insulation layer and the etching stop layer are then etched to form a trench for metal wiring. A barrier layer of Ti/TiN layer is formed over the insulation layer including the trench. An aluminum layer is deposited over the barrier layer with an AlCu layer interposed between to fill in the trench. The AlCu layer serves to prevent corrosion of the aluminum layer. The aluminum layer is chemical mechanical polished until the insulation layer is exposed, thereby forming a metal wiring.

The chemical mechanical polishing is performed such that the surface of the aluminum layer is oxidated using slurry having an oxidant added. The oxidated aluminum layer is then removed using slurry including a colloidal silica abrasive or alumina (Al₂O₃) abrasive.

However, in the prior art, corrosion is generated in the aluminum layer after the chemical mechanical polishing thereby lowering device properties and device reliability.

Specifically, the chemical mechanical polishing includes a post cleaning process that is performed in a brush manner or a wet bath manner using an ammonia or hydrofluoric acid-based etchant solution to remove slurry residue and polish by-product generated in the polishing process. In this case, the etchant penetrates into the surface of the aluminum layer or corrosion is caused by deionized water in the post cleaning process.

FIG. 2 is a photograph showing that corrosion is generated when forming a metal wiring using an aluminum layer.

As described above, defects and corrosion are generated on the resultant substrate when performing a post cleaning process of chemical mechanical polishing in accordance with the prior art for removing slurry residue and by polishing by-product generated in the polishing process. Since this results in a lowering of device properties and device reliability, it is necessary to improve the post cleaning process.

### BRIEF SUMMARY OF THE INVENTION

Embodiments of the present invention are directed to a method for chemical mechanical polishing of a semiconductor device, in which device properties and device reliability can be enhanced by improving detailed processes when forming a recess gate.

Further, embodiments of the present invention are directed to a method for chemical mechanical polishing of a semiconductor device, in which device properties and device reliability can be enhanced by improving detailed processes when forming a metal wiring using a damascene process.

In one embodiment, a method for chemical mechanical polishing of a semiconductor device may comprise polishing a target layer to be polished; and performing a post cleaning of the surface of the polished target layer including cleaning, rinsing and drying procedures, wherein parts for the cleaning, rinsing and drying procedures are arranged in a row, wherein the post cleaning is performed in a scan manner using a bar type module having a solution supplying nozzle and a retrieving nozzle which are disposed at the cleaning and rinsing parts, and wherein a solution supplied to a target layer to be polished is removed immediately after the solution comes in contact with the target layer.

In the cleaning and rinsing procedures, a contact time between the cleaning and rinsing solutions and the target layer to be polished is 0.1 to 10 seconds.

The scan manner using the bar type module is repeatedly performed at least two time.

In another embodiment, a method for chemical mechanical polishing of a semiconductor device, may comprise polishing a polysilicon layer formed to fill in a recess for a recess gate; and performing a post cleaning of the surface of the polished polysilicon layer including cleaning, rinsing and drying procedures, wherein parts for the cleaning, rinsing and drying procedures are arranged in a row, wherein the post cleaning is performed in a scan manner using a bar type module having a solution supplying nozzle and a retrieving nozzle disposed at both sides of the solution supplying nozzle which are disposed at the cleaning and rinsing parts, and wherein a solution supplied to a polysilicon layer to be polished is removed immediately after the solution comes in contact with the polysilicon layer.

The cleaning of the post cleaning is performed using a mixture solution of deionized water, diluted HF and H₂O₂ as a cleaning solution.

The diluted HF has a concentration of 0.1 wt % to 5 wt %.

The H₂O₂ has a concentration of 1 vol % to 25 vol %.

The cleaning of the post cleaning is performed using cleaning solution at a temperature of 20° C. to 80° C.

The rinsing of the post cleaning is performed using deionized water.

In the cleaning and rinsing procedures of the post cleaning, a contact time between the cleaning and rinsing solutions and the polysilicon layer to be polished is 0.1 seconds to 10 seconds.

The drying of the post cleaning is performed using a mixture of isopropylene alcohol (IPA) and N₂.

The scan manner using the bar type module is repeatedly performed at least two time.

In further another embodiment, a method for chemical mechanical polishing of a semiconductor device, may comprise polishing a metal layer formed to fill in a trench for a metal wiring; and performing a post cleaning of the surface of the polished metal layer including cleaning, rinsing and drying procedures, wherein parts for the cleaning, rinsing and drying procedures are arranged in a row, wherein the post cleaning is performed in a scan manner using a bar type module having a solution supplying nozzle and a retrieving nozzle disposed at both sides of the solution supplying nozzle which are disposed at the cleaning and rinsing parts, and wherein a solution supplied to a metal layer to be polished is removed immediately after the solution comes in contact with the metal layer.

The metal layer comprises an aluminum layer.

The cleaning of the post cleaning is performed using a mixture solution of deionized water, H₂SO₄, diluted HF and H₂O₂ as a cleaning solution.

The H₂SO₄ has a concentration of 0.1 vol % to 10 vol %.

The diluted HF has a concentration of 50 ppm to 500 ppm.

The H₂O₂ has a concentration of 0.2 vol % to 25 vol %.

The cleaning of the post cleaning is performed using cleaning solution at a temperature of 20° C. to 80° C.

The rinsing of the post cleaning is performed using deionized water.

The cleaning and rinsing procedures of the post cleaning, a contact time between the cleaning and rinsing solutions and the metal layer to be polished is 0.1 seconds to 10 seconds.

The drying of the post cleaning is performed using a mixture of isopropylene alcohol (IPA) and N₂.

The scan manner using the bar type module is repeatedly performed at least two time.

### BRIEF DESCRIPTION OF THE DRAWINGS

FIGS. 1A and 1B are black-and-white photographs illustrating problems in the prior art.

FIG. 2 is a black-and-white photograph illustrating another problem in the prior art.

FIG. 3 is a view illustrating a post cleaning in a method for chemical mechanical polishing in accordance with an embodiment of the present invention.

FIG. 4 is a view illustrating a bar type module for the post cleaning in accordance with an embodiment of the present invention.

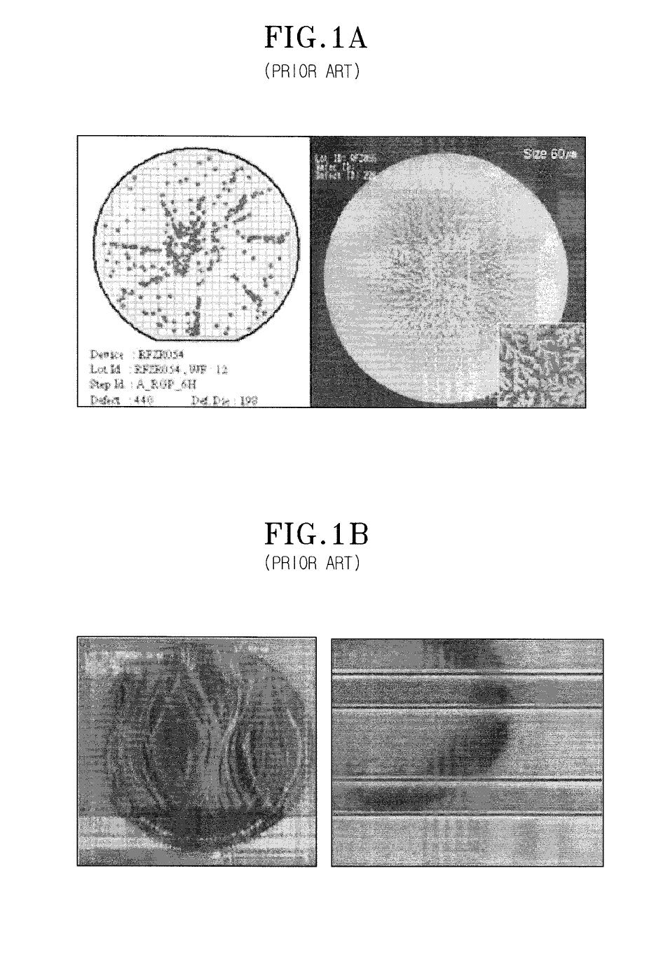

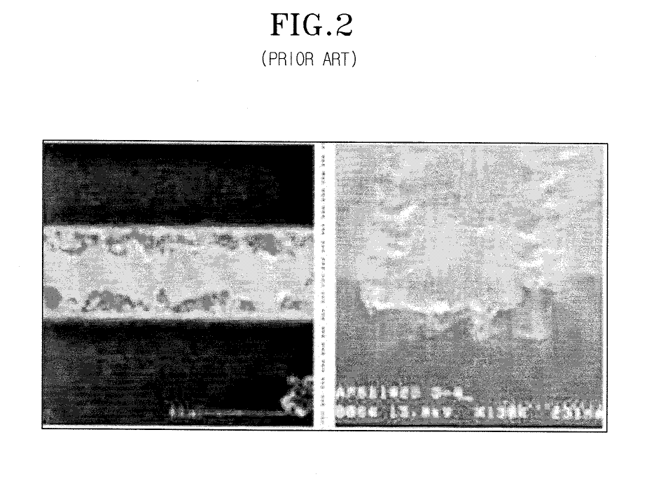

### DESCRIPTION OF SPECIFIC EMBODIMENTS

A preferred embodiment of the present invention is directed to a method for chemical mechanical polishing of a semiconductor device in which the chemical mechanical polishing process includes a post cleaning composed of cleaning, rinsing and drying performed in a scan manner using a bar type module. The bar type module having a solution supplying nozzle and a retrieving nozzle disposed at both sides of the solution supplying nozzle. Then, removing the solution supplied to a target layer to be polished immediately after the solution comes in contact with the target layer.

Therefore, since it is possible to minimize the contact time between cleaning and rinsing solutions and the target layer to be polished in cleaning and rinsing procedures while preventing contact with atmosphere during a drying procedure, it is possible to improve the chemical mechanical polishing process and therethrough enhance the device properties and device reliability.

Specifically, a method for manufacturing a semiconductor device including a chemical mechanical polishing in accordance with an embodiment of the present invention will be described.

First, an isolation layer defines an active region and an isolation region of a semiconductor substrate. The semiconductor substrate having the active region defined by the isolation layer is etched to form a gate recess. Then, a gate insulation layer is formed over the whole surface of the substrate including the gate recess. A polysilicon layer is further deposited over the gate insulation layer to fill the gate recess. The polysilicon layer is deposited with an uneven surface because it is formed to fill the gate recess. The unevenness over the surface of the polysilicon layer should be removed since it causes abnormal oxidation of a metal-based layer, shortage of a gate electrode, and SAC failure.

Subsequently, a chemical mechanical polishing for removing the uneven surface of the polysilicon layer is performed. A metal-based layer, for example a tungsten silicide layer, is deposited over the chemical mechanical polished polysilicon layer and a hard mask layer is deposited over the metal-based layer. The hard mask layer, the metal-based layer, the polysilicon layer, and the gate insulation layer are sequentially etched. Thereafter, known follow up processes are sequentially performed to form a recess gate over the gate recess.

Hereafter, the chemical mechanical polishing for removing the uneven surface of the polysilicon layer will be described with reference to the attached drawings.

The chemical mechanical polishing is performed such that a target layer to be polished is polished through a chemical reaction by slurry and a mechanical process by a polishing pad. Then a post cleaning composed of cleaning, rinsing, and drying is performed on the surface of the polished target layer.

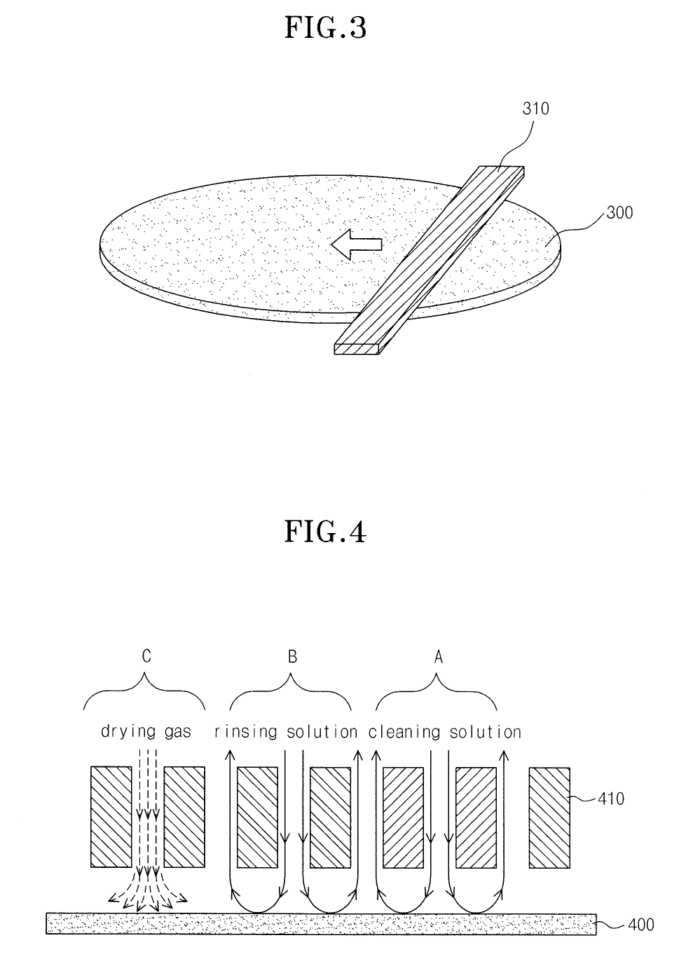

FIG. 3 is a view illustrating the post cleaning in accordance with an embodiment of the present invention.

As shown, the post cleaning of the present invention is performed such that a bar type module 310 scans a semiconductor substrate 300 deposited with a gate recess (not shown) and a polysilicon layer (not shown) for filling in the gate recess.

FIG. 4 is a view illustrating a bar type module in accordance with an embodiment of the present invention.

As shown, the bar type module for scanning the semiconductor substrate 400 is composed of three parts A, B and C for cleaning, rinsing and drying procedures respectively. In the cleaning part A, a cleaning solution is supplied to remove particles through chemical reaction. In the rinsing part B, a rinsing solution is supplied to remove residue of the solution used in the cleaning procedure. In the drying part C, drying gas is supplied to dry the surface of the semiconductor substrate 400 that has been in contact with the rinsing solution.

The cleaning and rinsing parts A and B are provided with a solution supplying nozzle (not shown) for supplying the cleaning solution and rinsing solution therethrough. A retrieving nozzle (not shown) is also provided disposed at both sides of the solution supplying nozzle for retrieving the cleaning solution and rinsing solution after the cleaning and rinsing procedures, respectively. The retrieving nozzle removes the supplied solution due to a pressure difference immediately after the solution comes in contact with the semiconductor substrate 400 to minimize contact time between the cleaning and rinsing solutions and the semiconductor substrate 400 in the cleaning and rinsing procedures and to prevent contact with atmosphere in the drying procedure. In this procedure, a suitable interface is maintained among the three parts A, B and C so that each solution is not mixed with other solutions.

The cleaning solution is a mixture of deionized water, diluted HF, and H₂O₂ at a temperature of 20° C. to 80° C. The diluted HF is mixed into the solution in a concentration of 0.1% to 5% by weight to remove particles of the oxide layer material that are a by-product of polishing. The H₂O₂ is mixed into the solution in a concentration of 1% to 25% by volume to serve as an oxidant that forms an oxide layer over the surface of the polysilicon layer and thus transforms the surface of the polysilicon layer from hydrophobicity to hydrophilicity after the chemical mechanical polishing. Further, the rinsing is performed using deionized water and the drying is performed using a mixture of isopropylene alcohol (IPA) and N₂.

The post cleaning performed in the scan manner using the bar type module is performed repeatedly at least two time, thereby completing the chemical mechanical polishing of a semiconductor device including the post cleaning.

As described above, in an embodiment of the present invention, since the post cleaning is performed in a scan manner using the bar type module provided with a supplying nozzle and retrieving nozzle instead of the conventional brush manner or wet bath manner, it is possible to significantly shorten the contact time between the cleaning and rinsing solutions and the semiconductor substrate to less than 10 seconds, preferably between 0.1 seconds to 10 seconds, as well as prevent the semiconductor substrate from being in contact with atmosphere in the drying procedure. It is therefore possible to relatively reduce the watermark defect generation as compared to the prior art.

Also, in an embodiment of the present invention, a cleaning solution containing H₂O₂, that serves as oxidant when cleaning, makes it possible to transform the hydrophobic surface of the polysilicon layer to hydrophilicity. Therefore, it is possible to reduce the watermark defect generation even more, thereby preventing poor gate patterning caused by the defect.

Furthermore, in an embodiment of the present invention, since the supplied solution is retrieved from the semiconductor substrate through the retrieving nozzle, various chemical residues and particles generated during the cleaning procedure are removed together allowing for an always fresh supply of solution. Also, it is possible to prevent the absorption of particles removed from the surface of the semiconductor substrate from being absorbed by another portion of the substrate.

Therefore, in an embodiment of the present invention, by improving the chemical mechanical polishing process including the post cleaning composed of the cleaning, rinsing and drying, it is possible to improve abnormal oxidation of the tungsten silicide layer due to a step height of the polysilicon layer. It is also possible to reduce SAC failure, which occurs in 50 per die in the prior art, to less than 10 per die according to an embodiment of the present invention. Accordingly, it is possible to enhance the device properties and device reliability.

Meanwhile, a method of improving a chemical mechanical polishing process for the planarization of a polysilicon layer having an uneven surface when forming a recess gate is described in the aforementioned embodiment of the present invention. Another embodiment of the present invention describes the chemical mechanical polishing process being performed in the same manner as the aforementioned embodiment when forming a metal wiring using a damascene process.

Hereafter, a method for forming a metal wiring using the damascene process will be briefly described.

An etch stop nitride layer and an insulation layer are sequentially deposited over a semiconductor substrate. The insulation layer is then etched to form a trench for metal wiring. A barrier layer is formed of a layer such as Ti/TiN, Ti/TiN/Ti, Ta/TaN, Ta/TaN/Ta, Ti/TiSiN and Ti/TiSiN/Ti over the whole surface of the substrate including the metal wiring trench. An aluminum layer is then deposited with an AlCu layer interposed over the barrier layer to fill in the metal wiring trench. The reason for depositing the aluminum layer with the AlCu layer interposed between is because the AlCu layer serves to prevent generation of galvanic corrosion between the aluminum layer and barrier layer. In other words, when depositing the aluminum layer that may cause galvanic corrosion between the barrier layer and aluminum layer because of its strong anodic properties, forming the AlCu layer having Cu that has strong cathodic properties can inhibit the galvanic corrosion.

The aluminum layer is chemical mechanical polished using slurry having an oxidant added until the insulation layer is exposed. The chemical mechanical polishing is performed using weak acidic slurry having a pH of 4 to 6 so as to oxidate the surface of the aluminum layer. One of H₂O₂, Fe(NO₃)₃ and H₅IO₆ is added to the slurry as the oxidant for oxidating the aluminum layer. Also, the chemical mechanical polishing is performed using slurry including a colloidal silica abrasive or alumina (Al₂O₃) abrasive.

The chemical mechanical polishing for planarization of the aluminum layer includes a post cleaning composed of cleaning, rinsing and drying. The post cleaning is performed such that a bar type module 310 (or 410) scans a semiconductor substrate 300 (or 400), as shown in FIGS. 3 and 4.

Also, since the chemical mechanical polishing should be performed so as not to corrode the aluminum layer, a NH₄OH or HF based solution cannot be used because it causes corrosion of the aluminum layer. Therefore, chemical mechanical polishing using a solution in which an anticorrosive agent is added into a solvent such as deionized water and having a pH of 8 to 10 is preferred.

Specifically, in the post cleaning of the chemical mechanical polishing for planarization of the aluminum layer, the cleaning is performed using a mixture solution of deionized water, H₂SO₄, diluted HF, and H₂O₂ at a temperature of 20° C. to 80° C. The H₂SO₄ removes organic components or other polymers remaining on the semiconductor substrate and is mixed into the solution in a concentration of 0.1% to 10% by volume. The diluted HF removes particles of the oxide layer material that are polishing by-products and is mixed into the solution in extremely low amount, preferably a concentration of 50 ppm to 500 ppm. The H₂O₂ prevents the corrosion of the aluminum layer and also removes the particles of the oxide layer material and is mixed into the solution in a concentration of 2% to 25% by volume.

The post cleaning performed in the scan manner using the bar type module is performed repeatedly at least two time. Thereby the chemical mechanical polishing of a semiconductor device including the post cleaning is completed.

In an embodiment of the present invention, since the post cleaning is performed in a scan manner using the bar type module provided with a supplying nozzle and retrieving nozzle, it is possible to significantly shorten the contact time between the cleaning and rinsing solutions and the semiconductor substrate to less than 10 seconds, preferably to 0.1 seconds to 10 seconds, as well as to prevent the semiconductor substrate from being in contact with atmosphere in the drying procedure. It is therefore possible to effectively prevent the corrosion of the metal wiring due to the cleaning or rinsing solution.

Also, in an embodiment of the present invention, since the supplied solution is retrieved from the semiconductor substrate through the retrieving nozzle, it is possible to improve the efficiency of the post cleaning by quick solution exchange. Also, since there is no delay time between the cleaning, rinsing and drying procedures, it is possible to inhibit watermark generation due to a difference in surface properties of the semiconductor substrate.

Furthermore, in an embodiment of the present invention, since the supplied solution is retrieved from the semiconductor substrate through the retrieving nozzle, various chemical residue and particles generated during the cleaning procedure are removed together allowing for an always fresh supply of solution. Also, it is possible to prevent the absorption of particles removed from the surface of the semiconductor substrate from being absorbed by another portion of the substrate. It is also possible to simultaneously clean the front and rear surfaces of the substrate.

Therefore, in an embodiment of the present invention, by improving the chemical mechanical polishing process including the post cleaning composed of the cleaning, rinsing and drying, it is possible to prevent corrosion of the aluminum layer due to penetration of the cleaning solution or deionized water. Accordingly, it is possible to enhance the device properties and device reliability.

As is apparent from the above description, in an embodiment of the present invention, it is possible to reduce the generation of a watermark defect and thereby prevent poor gate patterning caused by the defect when forming a recess gate since the chemical mechanical polishing process including the post cleaning composed of the cleaning, rinsing and drying is improved. Also, when forming a metal wiring using a damascene process, it is possible to prevent corrosion of the aluminum layer due to the cleaning solution or the rinsing solution since the chemical mechanical polishing process including the post cleaning composed of the cleaning, rinsing and drying is improved.

Therefore, in an embodiment of the present invention, it is possible to enhance the device properties and device reliability by improving the chemical mechanical polishing process including the post cleaning composed of the cleaning, rinsing and drying.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A method for chemical mechanical polishing of a semiconductor device, comprising the steps of:
polishing a target layer to be polished; and
performing a post cleaning of the surface of the polished target layer including cleaning, rinsing, and drying procedures,
wherein parts for the cleaning, rinsing and drying procedures of the post cleaning are arranged in a row,
wherein the post cleaning is performed in a scan manner using a bar type module having a solution supplying nozzle and a retrieving nozzle disposed at both sides of the solution supplying nozzle which are disposed at the cleaning and rinsing parts, and
wherein a solution supplied to a target layer to be polished is removed immediately after the solution comes in contact with the target layer.

2. The method for chemical mechanical polishing of a semiconductor device according to claim 1, wherein during the cleaning and rinsing procedures of the post cleaning, a contact time between cleaning and rinsing solutions and the target layer to be polished is 0.1 seconds to 10 seconds.

3. The method for chemical mechanical polishing of a semiconductor device according to claim 1, wherein the scan manner using the bar type module is repeatedly performed at least two time.

4. A method for chemical mechanical polishing of a semiconductor device, comprising the steps of:
polishing a a polysilicon layer formed to fill in a recess for a recess gate; and
performing a post cleaning of the surface of the polished polysilicon layer including cleaning, rinsing and drying procedures,
wherein parts for the cleaning, rinsing and drying procedures of the post cleaning are arranged in a row,
wherein the post cleaning is performed in a scan manner using a bar type module having a solution supplying nozzle and a retrieving nozzle disposed at both sides of the solution supplying nozzle which are disposed at the cleaning and rinsing parts, and
wherein a solution supplied to a polysilicon layer to be polished is removed immediately after the solution comes in contact with the polysilicon layer.

5. The method for chemical mechanical polishing of a semiconductor device according to claim 4, wherein the cleaning procedure of the post cleaning is performed using a solution mixture of deionized water, diluted HF and H₂O₂ as a cleaning solution.

6. The method for chemical mechanical polishing of a semiconductor device according to claim 5, wherein the diluted HF has a concentration of 0.1 wt % to 5 wt %.

7. The method for chemical mechanical polishing of a semiconductor device according to claim 5, wherein the H₂O₂ has a concentration of 1 vol % to 25 vol %.

8. The method for chemical mechanical polishing of a semiconductor device according to claim 4, wherein the cleaning procedure of the post cleaning is performed using a cleaning solution at a temperature of 20° C. to 80° C.

9. The method for chemical mechanical polishing of a semiconductor device according to claim 4, wherein the rinsing procedure of the post cleaning is performed using deionized water.

10. The method for chemical mechanical polishing of a semiconductor device according to claim 4, wherein during the cleaning and rinsing procedures of the post cleaning, a contact time between cleaning and rinsing solutions and the polysilicon layer to be polished is 0.1 seconds to 10 seconds.

11. The method for chemical mechanical polishing of a semiconductor device according to claim 4, wherein the drying procedure of the post cleaning is performed using a mixture of isopropylene alcohol (IPA) and N₂.

12. The method for chemical mechanical polishing of a semiconductor device according to claim 4, wherein the scan manner using the bar type module is repeatedly performed at least two time.

13. A method for chemical mechanical polishing of a semiconductor device, comprising the steps of:
polishing a metal layer formed to fill in a trench for a metal wiring; and
performing a post cleaning of the surface of the polished metal layer including cleaning, rinsing and drying procedures,
wherein parts for the cleaning, rinsing and drying procedures are arranged in a row,
wherein the post cleaning is performed in a scan manner using a bar type module having a solution supplying nozzle and a retrieving nozzle disposed at both sides of the solution supplying nozzle which are disposed at the cleaning and rinsing parts, and
wherein a solution supplied to a metal layer to be polished is removed immediately after the solution comes in contact with the metal layer.

14. The method for chemical mechanical polishing of a semiconductor device according to claim 13, wherein the metal layer comprises an aluminum layer.

15. The method for chemical mechanical polishing of a semiconductor device according to claim 13, wherein the cleaning procedure of the post cleaning is performed using a solution mixture of deionized water, H₂SO₄, diluted HF and H₂O₂ as a cleaning solution.

16. The method for chemical mechanical polishing of a semiconductor device according to claim 15, wherein the H₂SO₄ has a concentration of 0.1 vol % to 10 vol %.

17. The method for chemical mechanical polishing of a semiconductor device according to claim 15, wherein the diluted HF has a concentration of 50 ppm to 500 ppm.

18. The method for chemical mechanical polishing of a semiconductor device according to claim 15, wherein the H₂O₂ has a concentration of 0.2 vol % to 25 vol %.

19. The method for chemical mechanical polishing of a semiconductor device according to claim 13, wherein the cleaning procedure of the post cleaning is performed using a cleaning solution at a temperature of 20° C. to 80° C.

20. The method for chemical mechanical polishing of a semiconductor device according to claim 13, wherein the rinsing procedure of the post cleaning is performed using deionized water.

21. The method for chemical mechanical polishing of a semiconductor device according to claim 13, wherein during the cleaning and rinsing procedures of the post cleaning, a contact time between cleaning and rinsing solutions and the metal layer to be polished is 0.1 seconds to 10 seconds.

22. The method for chemical mechanical polishing of a semiconductor device according to claim 13, wherein the drying procedure of the post cleaning is performed using a mixture of isopropylene alcohol (IPA) and N₂.

23. The method for chemical mechanical polishing of a semiconductor device according to claim 13, wherein the scan manner using the bar type module is repeatedly performed at least two time.
